(19) United States
(12) Patent Application Publication
(10) Pub. No.: US 2013/0240872 A1
(43) Pub. Date: Sep. 19, 2013

(54) SEMICONDUCTOR DEVICE

(71) Applicant: SEMICONDUCTOR ENERGY LABORATORY CO., LTD., Atsugi-shi (JP)

(72) Inventor: Kosei NODA, Atsugi (JP)

(73) Assignee: SEMICONDUCTOR ENERGY LABORATORY CO., LTD., Atsugi-shi (JP)

(21) Appl. No.: 13/790,248

(22) Filed: Mar. 8, 2013

(30) Foreign Application Priority Data
Mar. 14, 2012 (JP) 2012-057738

(51) Int. Cl. H01L 29/786

(52) U.S. Cl. CPC H01L 29/78696
USPC 257/43

(57) ABSTRACT

In the transistor including a gate electrode and an oxide semiconductor film which are provided to overlap with each other with a gate insulating film provided therebetween and a first electrode and a second electrode which are in contact with the oxide semiconductor film, the second electrode partly surrounds an end portion and side surface portions of the first electrode. In the oxide semiconductor film, a channel region is formed in a region which overlaps with the gate electrode and which is between the first electrode and the second electrode. An end portion of the oxide semiconductor film which continuously extends from end portions of the channel region does not overlap with the gate electrode.

### BACKGROUND OF THE INVENTION

1. Field of the Invention

The present invention relates to a semiconductor device provided with a transistor including an oxide semiconductor film.

2. Description of the Related Art

Attention has been focused on a technique for forming a transistor (also referred to as a thin film transistor (TFT)) using a semiconductor thin film formed over a substrate. The transistor is applied to a wide range of electronic devices such as an integrated circuit (IC) or an image display device (display device). A silicon-based semiconductor material is widely known as a material for a semiconductor thin film applicable to a transistor. As another material, an oxide semiconductor has been attracting attention.

For example, a transistor including an oxide semiconductor containing indium (In), gallium (Ga), and zinc (Zn) as an active layer is disclosed (see Patent Document 1).

### REFERENCE

[Patent Document 1] Japanese Published Patent Application No. 2006-165528

### SUMMARY OF THE INVENTION

Further, in a transistor including an oxide semiconductor, in the transistor characteristics (a drain current-a gate voltage curve (Id-Vg curve)) after a gate BT stress (in particular, a negative bias) is applied, a defect of a stepwise rise of a drain current occurs at around the threshold voltage and a hump-like curve is observed in the Id-Vg curve. It is thought that this is caused by a formation of a parasitic channel due to a change to an n-type oxide semiconductor at a side surface of the oxide semiconductor film which overlaps with a gate electrode. The side surface of the oxide semiconductor film is contaminated by damage due to processing for element isolation, the attachment of impurities, or the like. Therefore, when stress such as an electric field is applied to the region, the region is easily activated, thereby becoming n-type (having a low resistance), so that a parasitic channel is formed.

One object of one embodiment of the present invention is to provide a semiconductor device which includes an oxide semiconductor and in which formation of a parasitic channel due to a gate BT stress is suppressed. Further, a semiconductor device including a transistor having excellent electrical characteristics is provided.

In one embodiment of the present invention, in a transistor including a gate electrode and an oxide semiconductor film which are provided to overlap with each other with a gate insulating film provided therebetween and a first electrode and a second electrode which are in contact with the oxide semiconductor film, the second electrode partly surrounds an end portion and side surface portions of the first electrode. In the oxide semiconductor film, a channel region is formed in a region which overlaps with the gate electrode and which is between the first electrode and the second electrode. An end portion of the oxide semiconductor film which continuously extends from end portions of the channel region does not overlap with the gate electrode.

Further, in one embodiment of the present invention, in a transistor including a gate electrode and an oxide semiconductor film which are provided to overlap with each other with a gate insulating film provided therebetween and a first electrode and a second electrode which are in contact with the oxide semiconductor film, the second electrode partly surrounds an end portion and side surface portions of the first electrode. In the oxide semiconductor film, a channel region is formed in a region which overlaps with the gate electrode and which is between the first electrode and the second electrode. An end portion of the oxide semiconductor film which intersects with a direction extending from a channel width direction does not overlap with the gate electrode.

Further, in one embodiment of the present invention, in a transistor including a gate electrode and an oxide semiconductor film which are provided to overlap with each other with a gate insulating film provided therebetween and a first electrode and a second electrode which are in contact with the oxide semiconductor film, the second electrode partly surrounds an end portion and side surface portions of the first electrode. In the oxide semiconductor film, a channel region is formed in a region which overlaps with the gate electrode and which is between the first electrode and the second electrode. The oxide semiconductor film has a region not overlapping with the gate electrode, in the vicinity of the channel region or in contact with the channel region.

In one embodiment of the present invention, the semiconductor device has the oxide semiconductor film containing one or more elements selected from In, Ga, Sn, and Zn.

In one embodiment of the present invention, the end portion of the oxide semiconductor film positioned in the vicinity of the channel region does not overlap with the gate electrode. Therefore, stress such as an electric field is not applied to the end portion of the oxide semiconductor film and the end portion of the oxide semiconductor film does not easily become n-type. Thus, a parasitic channel is not easily formed between the pair of electrodes through the end portion, which enables suppression of the occurrence of defects in electric characteristics of the transistor.

According to one embodiment of the present invention, a semiconductor device which includes an oxide semiconductor and in which formation of a parasitic channel due to a gate BT stress is suppressed can be provided. Further, according to one embodiment of the present invention, a semiconductor device including a transistor having excellent electrical characteristics can be provided.

### BRIEF DESCRIPTION OF THE DRAWINGS

FIG. 1A is a top view illustrating a semiconductor device of one embodiment of the present invention and FIG. 1B is a cross-sectional view thereof.

FIGS. 2A to 2D are cross-sectional views illustrating a manufacturing method of a semiconductor device of one embodiment of the present invention.

FIG. 3 is a top view illustrating a semiconductor device of one embodiment of the present invention.

FIG. 4 is a top view illustrating a semiconductor device of one embodiment of the present invention.

FIG. 5 is a top view illustrating a semiconductor device of one embodiment of the present invention.

FIGS. 6A to 6C are top views illustrating semiconductor devices of one embodiment of the present invention.

FIGS. 7A and 7B are cross-sectional views illustrating semiconductor devices of one embodiment of the present invention.

### DETAILED DESCRIPTION OF THE INVENTION

Embodiments of the present invention will be described below with reference to the accompanying drawings. Note that the present invention is not limited to the description below, and it is easily understood by those skilled in the art that various changes and modifications can be made without departing from the spirit and scope of the present invention. Therefore, the present invention should not be construed as being limited to the description in the following embodiments. Note that the same portions or portions having the same function in the structure of the present invention described below are denoted by the same reference numerals in common among different drawings and repetitive description thereof will be omitted.

Note that in each drawing described in this specification, the size, the film thickness, or the region of each component is exaggerated for clarity in some cases. Therefore, embodiments of the present invention are not limited to such scales.

Note that terms such as “first”, “second”, and “third” in this specification are used in order to avoid confusion among components, and the terms do not limit the components numerically. Therefore, for example, the term “first” can be replaced with the term “second”, “third”, or the like as appropriate.

### Embodiment 1

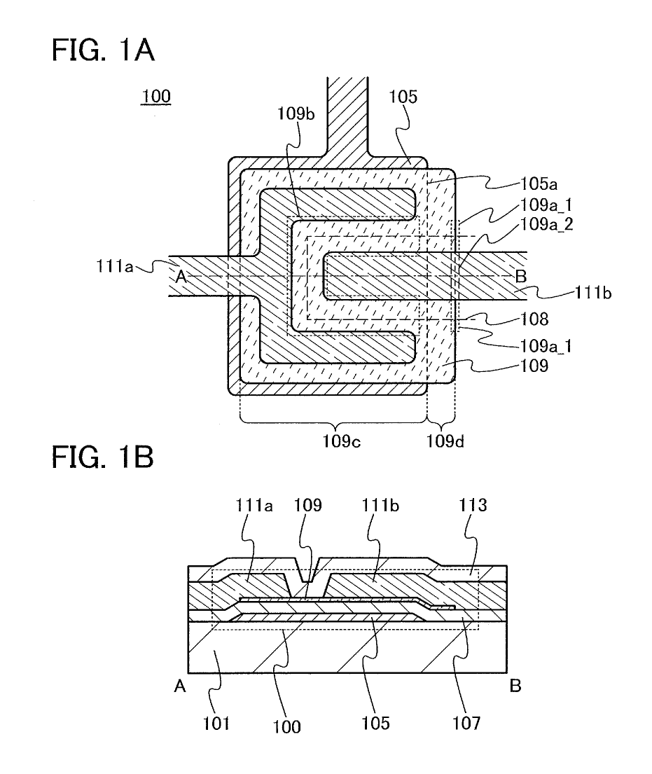

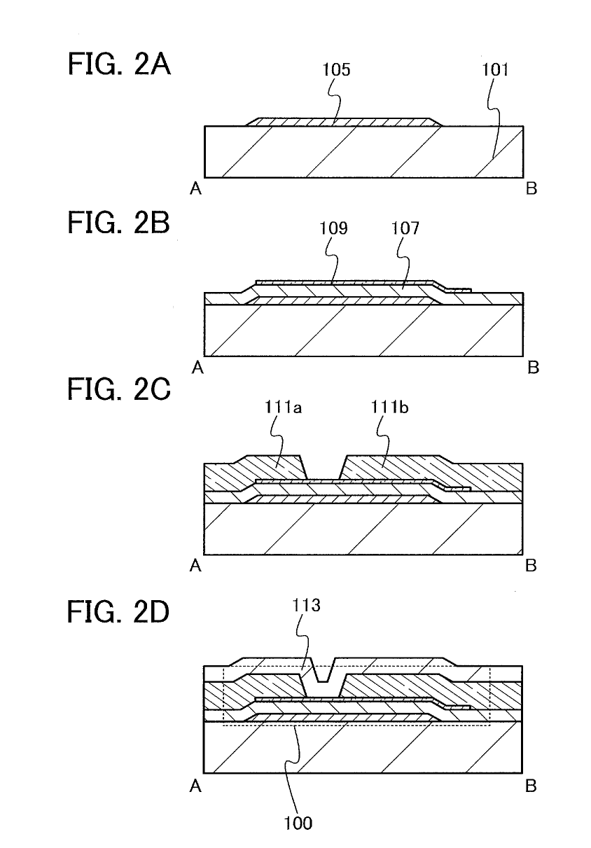

In this embodiment, a structure of a transistor having excellent electrical characteristics and a method for manufacturing the transistor with high productivity are described with reference to FIGS. 1A and 1B and FIGS. 2A to 2D.

FIGS. 1A and 1B are a top view and a cross-sectional view of a transistor 100 described in this embodiment. FIG. 1A is a top view of the transistor 100 illustrated in this embodiment and FIG. 1B is a cross-sectional view of the transistor 100 along a dashed-dotted line A-B in FIG. 1A. Note that some components (e.g., a gate insulating film 107) of the transistor 100 are not illustrated in FIG. 1A for simplicity.

The transistor 100 illustrated in FIG. 1B includes a gate electrode 105 provided over a substrate 101, the gate insulating film 107 covering at least the gate electrode 105, an oxide semiconductor film 109 overlapping with part of the gate electrode 105 with the gate insulating film 107 provided therebetween, and a pair of electrodes 111a and 111b which are formed in contact with the oxide semiconductor film 109. Further, an insulating film 113 covering the transistor 100 may be provided. Furthermore, although not shown, a base insulating film may be provided between the substrate 101 and the gate electrode 105.

As illustrated in FIG. 1A, as for the pair of electrodes 111a and 111b of the transistor 100 described in this embodiment, the electrode 111a partly surrounds an end portion and side surface portions of the electrode 111b. Specifically, the electrode 111a partly surrounds the electrode 111b with a certain space interposed therebetween. Note that in the oxide semiconductor film 109, a region where the pair of electrodes 111a and 111b face each other, that is, the region which is interposed between the electrode 111a and the electrode 111b and which overlaps with the gate electrode 105 serves as a channel region 109b.

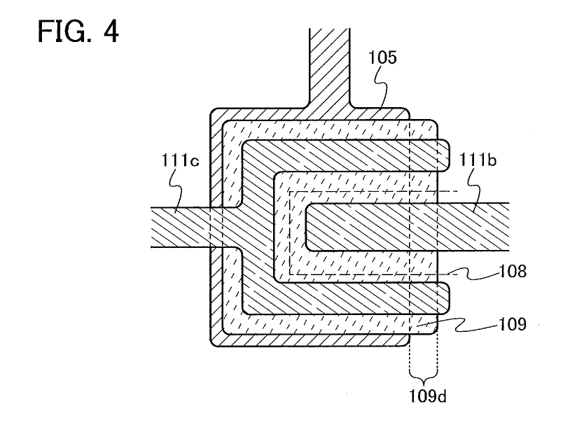

Further, in the oxide semiconductor film 109, an end portion of the oxide semiconductor film which continuously extends from end portions of the channel region 109b does not overlap with the gate electrode 105. That is, as illustrated in FIG. 1A, a region 109d not overlapping with the gate electrode 105 is in the vicinity of the channel region 109b. Alternatively, as illustrated in FIG. 4, the oxide semiconductor film 109 includes the region 109d in contact with the channel region 109b and not overlapping with the gate electrode 105.

Further, the end portion of the oxide semiconductor film 109 which intersects with a direction 108 extending from a channel width direction of the transistor 100, in other words, the direction 108 extending from a direction intersecting with a direction in which the electrodes 111a and 111b face each other (that is, channel length direction) does not overlap with the gate electrode 105.

Furthermore, the oxide semiconductor film 109 includes a region not overlapping with the gate electrode 105, that is, part of the region 109d, between a region 109c overlapping with the electrode 111a and an end portion 109a_2 overlapping with the electrode 111b. That is, in the oxide semiconductor film 109, the region not overlapping with the gate electrode 105 is provided between the channel region 109b and the end portion of the oxide semiconductor film 109.

Further, in the oxide semiconductor film 109, end portions 109a_1 provided in the vicinity of the channel region 109b do not overlap with the gate electrode 105. That is, the end portions 109a_1 of the oxide semiconductor film 109 are positioned on the outer side than an end portion 105a of the gate electrode 105. Note that the end portions 109a_1 are adjacent to the end portion 109a_2 of the oxide semiconductor film overlapping with the electrode 111b and are the closest to the channel region 109b.

Since the end portion processed by etching or the like of the oxide semiconductor film is contaminated by damage due to processing, the attachment of an impurity, or the like, the end portion is easily activated by application of a stress such as an electric field, thereby easily becoming n-type (having a low resistance). Therefore, in the end portion of the oxide semiconductor film overlapping with the gate electrode, the oxide semiconductor easily becomes n-type. When the end portion which has turned to be n-type is provided between the pair of electrodes 111a and 111b, the region which has turned to be n-type serves as a carrier path, resulting in formation of a parasitic channel. However, in the case where the end portion of the oxide semiconductor film in the vicinity of the channel region does not overlap with the gate electrode, that is, in the case where the end portion of the oxide semiconductor film is positioned on the outer side than the gate electrode, an electric field is not applied to the end portion of the oxide semiconductor film and the end portion of the oxide semiconductor film does not become n-type; therefore, a leakage path is not caused. Thus, the transistor 100 can have excellent electric characteristics such as a sharp increase of the drain current at around the threshold voltage.

Further, in the oxide semiconductor film 109, a region other than the region 109d not overlapping with the gate electrode 105 and in the vicinity of the channel region 109b is a region 109c overlapping with the electrode 111a. Therefore, the amount of light emitted from the substrate 101 side to the oxide semiconductor film 109 can be minimized, so that an increase in the off-state current due to light-leakage current can be suppressed.

Here, details of the structure of the transistor 100 are described below.

There is no particular limitation on the property of a material and the like of the substrate 101 as long as the material has heat resistance enough to withstand at least heat treatment to be performed later. For example, a glass substrate, a ceramic substrate, a quartz substrate, a sapphire substrate, or the like may be used as the substrate 101. Alternatively, a single crystal semiconductor substrate or a polycrystalline semiconductor substrate made of silicon, silicon carbide, or the like, a compound semiconductor substrate made of silicon germanium or the like, an SOI substrate, or the like may be used as the substrate 101. Furthermore, any of these substrates further provided with a semiconductor element may be used as the substrate 101.

Still further alternatively, a flexible substrate may be used as the substrate 101, and the transistor 100 may be provided directly on the flexible substrate. Alternatively, a separation layer may be provided between the substrate 101 and the transistor 100. The separation layer can be used when part or the whole of a semiconductor device formed over the separation layer is separated from the substrate 101 and transferred onto another substrate. In such a case, the semiconductor device can be transferred to a substrate having low heat resistance or a flexible substrate as well.

The gate electrode 105 can be formed using a metal element selected from aluminum, chromium, copper, tantalum, titanium, molybdenum, tungsten, manganese, and zirconium; an alloy containing any of these metal elements as a component; an alloy containing any of these metal elements in combination; or the like. Furthermore, the gate electrode 105 may have a single-layer structure or a stacked-layer structure of two or more layers.

The gate electrode 105 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal element.

Further, an In—Ga—Zn-based oxynitride semiconductor film, an In—Sn-based oxynitride semiconductor film, an In—Ga-based oxynitride semiconductor film, an In—Zn-based oxynitride semiconductor film, a Sn-based oxynitride semiconductor film, an In-based oxynitride semiconductor film, a metal nitride (InN, ZnN, or the like) film is preferably provided between the gate electrode 105 and the gate insulating film 107. These films each have a work function of 5 eV or higher, preferably 5.5 eV or higher and the electron affinity of each of these films is larger than that of an oxide semiconductor; thus, the threshold voltage of the electrical characteristics of the transistor including an oxide semiconductor can be positive. Accordingly, what is called a normally-off switching element can be obtained. For example, in the case of using an In—Ga—Zn-based oxynitride semiconductor film, an In—Ga—Zn-based oxynitride semiconductor film having a nitrogen concentration higher than at least that of the oxide semiconductor film 109, specifically, an In—Ga—Zn-based oxynitride semiconductor film having a nitrogen concentration of 7 at. % or higher is used.

The gate insulating film 107 may be formed to have a stacked-layer structure or a single-layer structure using any of silicon oxide, silicon oxynitride, a Ga—Zn-based metal oxide film, aluminum oxide, aluminum oxynitride, gallium oxide, gallium oxynitride, yttrium oxide, yttrium oxynitride, hafnium oxide, hafnium oxynitride, and the like.

The thickness of the gate insulating film 107 may be greater than or equal to 100 nm and less than or equal to 350 nm, typically greater than or equal to 100 nm and less than or equal to 200 nm.

The oxide semiconductor film 109 preferably contains at least indium (In) or zinc (Zn). Alternatively, the oxide semiconductor film 109 preferably contains both In and Zn. In order to reduce variation in electrical characteristics of the transistor including the oxide semiconductor, the oxide semiconductor film 109 preferably contains one or more of stabilizers in addition to In or Zn.

As a stabilizer, gallium (Ga), tin (Sn), hafnium (Hf), aluminum (Al), zirconium (Zr), and the like can be given.

As another stabilizer, lanthanoid such as lanthanum (La), cerium (Ce), praseodymium (Pr), neodymium (Nd), samarium (Sm), europium (Eu), gadolinium (Gd), terbium (Tb), dysprosium (Dy), holmium (Ho), erbium (Er), thulium (Tm), ytterbium (Yb), lutetium (Lu), or the like can be given.

As the oxide semiconductor, for example, an indium oxide, a tin oxide, a zinc oxide, a two-component metal oxide such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide, a three-component metal oxide such as an In—Ga—Zn-based oxide (also referred to as IGZO), an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-based oxide, an In—Yb—Zn-based oxide, or an In—Lu—Zn-based oxide, or a four-component metal oxide such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, or an In—Hf—Al—Zn-based oxide can be used.

Note that here, for example, an “In—Ga—Zn-based oxide” means an oxide containing In, Ga, and Zn as its main component and there is no particular limitation on the ratio of In:Ga:Zn. The In—Ga—Zn-based oxide may contain a metal element other than the In, Ga, and Zn.

Alternatively, a material represented by InMO₃(ZnO)ₘ (m>0 is satisfied, and m is not an integer) may be used as an oxide semiconductor. Note that M represents one or more metal elements selected from Ga, Fe, Mn, and Co. Alternatively, as the oxide semiconductor, a material expressed by a chemical formula, In₂SnO₅(ZnO)ₙ (n>0 is satisfied, n is a natural number) may be used.

For example, an In—Ga—Zn-based oxide with an atomic ratio of In:Ga:Zn=1:1:1 (=1/3:1/3:1/3), In:Ga:Zn=2:2:1 (=2/5:2/5:1/5), In:Ga:Zn=3:1:2 (=1/2:1/6:1/3), or any of oxides whose composition is in the neighborhood of the above compositions can be used. Alternatively, an In—Sn—Zn-based oxide with an atomic ratio of In:Sn:Zn=1:1:1 (=1/3:1/3:1/3), In:Sn:Zn=2:1:3 (=1/3:1/6:1/2), or In:Sn:Zn=2:1:5 (=1/4:1/8:5/8), or any of oxides whose composition is in the neighborhood of the above compositions may be used.

However, the composition is not limited to those described above, and a material having the appropriate composition may be used depending on necessary semiconductor characteristics and electrical characteristics (e.g., field-effect mobility, threshold voltage, and variation). In order to obtain necessary semiconductor characteristics, it is preferable that the carrier density, the impurity concentration, the defect density, the atomic ratio of a metal element to oxygen, the interatomic distance, the density, and the like be set to be appropriate.

For example, high mobility can be obtained relatively easily in the case of using an In—Sn—Zn oxide. However, mobility can be increased by reducing the defect density in a bulk also in the case of using an In—Ga—Zn-based oxide.

Note that the energy gap of the metal oxide which can be used for the oxide semiconductor film 109 is 2 eV or higher, preferably 2.5 eV or higher, further preferably 3 eV or higher. In this manner, the off-state current of a transistor can be reduced by using an oxide semiconductor having a wide energy gap.

Note that the oxide semiconductor film 109 may have an amorphous structure, a single crystal structure, or a polycrystalline structure.

Note that the oxide semiconductor film 109 may be in a non-single-crystal state, for example. The non-single-crystal state is, for example, structured by at least one of c-axis aligned crystal (CAAC), polycrystal, microcrystal, and an amorphous part. The density of defect states of an amorphous part is higher than those of microcrystal and CAAC. The density of defect states of microcrystal is higher than that of CAAC. Note that an oxide semiconductor including CAAC is referred to as a CAAC-OS (c-axis aligned crystalline oxide semiconductor). In the CAAC-OS, for example, c-axes are aligned, and a-axes and/or b-axes are not macroscopically aligned.

For example, the oxide semiconductor film 109 may include microcrystal. Note that an oxide semiconductor including microcrystal is referred to as a microcrystalline oxide semiconductor. A microcrystalline oxide semiconductor film includes microcrystal (also referred to as nanocrystal) with a size greater than or equal to 1 nm and less than 10 nm, for example. Alternatively, a microcrystalline oxide semiconductor film, for example, includes a crystal-amorphous mixed phase structure where crystal parts (each of which is greater than or equal to 1 nm and less than 10 nm) are distributed.

For example, the oxide semiconductor film 109 may include an amorphous part. Note that an oxide semiconductor including an amorphous part is referred to as an amorphous oxide semiconductor. An amorphous oxide semiconductor film, for example, has disordered atomic arrangement and no crystalline component. Alternatively, an amorphous oxide semiconductor film is, for example, absolutely amorphous and has no crystal part.

Note that the oxide semiconductor film 109 may be a mixed film including any of a CAAC-OS, a microcrystalline oxide semiconductor, and an amorphous oxide semiconductor. The mixed film, for example, includes a region of an amorphous oxide semiconductor, a region of a microcrystalline oxide semiconductor, and a region of a CAAC-OS. Further, the mixed film may have a stacked structure including a region of an amorphous oxide semiconductor, a region of a microcrystalline oxide semiconductor, and a region of a CAAC-OS, for example.

Note that the oxide semiconductor film 109 may be in a single-crystal state, for example.

Here, details of a CAAC-OS film are described. The CAAC-OS film is not absolutely amorphous. The CAAC-OS film, for example, includes an oxide semiconductor with a crystal-amorphous mixed phase structure where crystal parts and amorphous parts are intermingled. Note that in most cases, the crystal part fits inside a cube whose one side is less than 100 nm. In an image obtained with a transmission electron microscope (TEM), a boundary between an amorphous part and a crystal part and a boundary between crystal parts in the CAAC-OS film are not clearly detected. Further, with the TEM, a grain boundary in the CAAC-OS film is not clearly found. Thus, in the CAAC-OS film, a reduction in electron mobility due to the grain boundary is suppressed.

In each of the crystal parts included in the CAAC-OS film, for example, a c-axis is aligned in a direction parallel to a normal vector of a surface where the CAAC-OS film is formed or a normal vector of a surface of the CAAC-OS film. Further, in each of the crystal parts, metal atoms are arranged in a triangular or hexagonal configuration when seen from the direction perpendicular to the a-b plane, and metal atoms are arranged in a layered manner or metal atoms and oxygen atoms are arranged in a layered manner when seen from the direction perpendicular to the c-axis. Note that, among crystal parts, the directions of the a-axis and the b-axis of one crystal part may be different from those of another crystal part. In this specification, a term “perpendicular” includes a range from 80° to 100°, preferably from 85° to 95°. In addition, a term “parallel” includes a range from −10° to 10°, preferably from −5° to 5°. Note that part of oxygen included in the oxide semiconductor film may be substituted with nitrogen.

In the CAAC-OS film, distribution of crystal parts is not necessarily uniform. For example, in the formation process of the CAAC-OS film, in the case where crystal growth occurs from a surface side of the oxide semiconductor film, the proportion of crystal parts in the vicinity of the surface of the oxide semiconductor film is higher than that in the vicinity of the surface where the oxide semiconductor film is formed in some cases. Further, when an impurity is added to the CAAC-OS film, the crystal part in a region to which the impurity is added becomes amorphous in some cases.

Since the c-axes of the crystal parts included in the CAAC-OS film are aligned in the direction parallel to a normal vector of a surface where the CAAC-OS film is formed or a normal vector of a surface of the CAAC-OS film, the directions of the c-axes may be different from each other depending on the shape of the CAAC-OS film (the cross-sectional shape of the surface where the CAAC-OS film is formed or the cross-sectional shape of the surface of the CAAC-OS film). Note that the film deposition is accompanied with the formation of the crystal parts or followed by the formation of the crystal parts through crystallization treatment such as heat treatment. Hence, the c-axes of the crystal parts are aligned in the direction parallel to a normal vector of the surface where the CAAC-OS film is formed or a normal vector of the surface of the CAAC-OS film.

In a transistor using the CAAC-OS film, change in electric characteristics due to irradiation with visible light or ultraviolet light is small. Thus, the transistor has high reliability.

The concentration of alkali metals or alkaline earth metals in the oxide semiconductor film 109 is preferably lower than or equal to 1×10¹⁸ atoms/cm³, further preferably lower than or equal to 2×10¹⁶ atoms/cm³. When alkali metals or alkaline earth metals are bonded to an oxide semiconductor, some of the alkali metals or the alkaline earth metals generate carriers and cause an increase in the off-state current of the transistor.

The oxide semiconductor film 109 may contain nitrogen at a concentration lower than or equal to 5×10¹⁸ atoms/cm³.

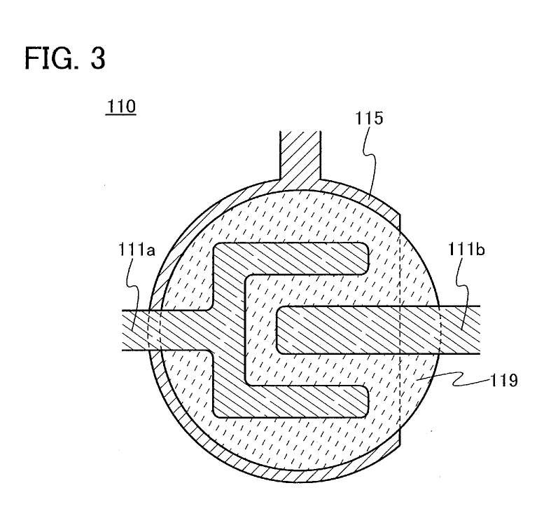

In the transistor 100 illustrated in FIGS. 1A and 1B, the oxide semiconductor film 109 has a rectangular upper surface. Further, in the gate electrode 105, a region overlapping with the oxide semiconductor film 109 has a rectangular shape. Note that the oxide semiconductor film 109 can have a circular upper surface, a polygonal upper surface, or the like as appropriate. Further, in the gate electrode 105, the shape of the region overlapping with the oxide semiconductor film 109 may be similar to that of the oxide semiconductor film 109. FIG. 3 illustrates a transistor 110 including a circular oxide semiconductor film 119 and a gate electrode 115 having a circular region overlapping with the oxide semiconductor film 119. When the oxide semiconductor film 119 has a circular upper surface, a corner portion is not formed at the end portion of the oxide semiconductor film 119 and the coverage with the oxide semiconductor film 119 at the end portion can be improved.

The pair of electrodes 111a and 111b is formed to have a single-layer structure or a stacked-layer structure including, as a conductive material, any of metals such as aluminum, titanium, chromium, nickel, copper, yttrium, zirconium, molybdenum, silver, tantalum, and tungsten and an alloy containing any of these metals as a main component. Note that a transparent conductive material containing indium oxide, tin oxide, or zinc oxide may be used. Note that the pair of electrodes 111a and 111b may also function as a wiring.

In FIG. 1A, the electrode 111a which is one of the pair of electrodes 111a and 111b does not overlap with the end portion of the oxide semiconductor film 109 in the vicinity of the channel region 109b and end portions of the electrode 111a are positioned over the oxide semiconductor film 109. However, as illustrated in FIG. 4 which is a top view, an electrode 111c may overlap with the end portion of the oxide semiconductor film 109 and end portions of the electrode 111c may be positioned on the outer side than the oxide semiconductor film 109.

The insulating film 113 may be formed with a single layer or a stack including one or more of silicon oxide, silicon oxynitride, silicon nitride oxide, silicon nitride, aluminum oxide, aluminum oxynitride, aluminum nitride oxide, aluminum nitride, and the like.

Next, a method for manufacturing the transistor 100 illustrated in FIGS. 1A and 1B is described with reference to FIGS. 2A to 2D.

As illustrated in FIG. 2A, a gate electrode 105 is formed over a substrate 101. A method for forming the gate electrode 105 is described below. First, a conductive film is formed by a sputtering method, a CVD method, an evaporation method, or the like. Then, a mask is formed over the conductive film by a photolithography process. Next, part of the conductive film is etched with use of the mask to form the gate electrode 105. After that, the mask is removed.

Note that the gate electrode 105 may be formed by an electrolytic plating method, a printing method, an ink-jet method, or the like instead of the above formation methods.

Here, a tungsten film having a thickness of 100 nm is formed by a sputtering method. Then, a mask is formed by a photolithography process and the tungsten film is dry-etched with use of the mask to form the gate electrode 105.

Next, as illustrated in FIG. 2B, the gate insulating film 107 is formed so as to cover at least the gate electrode 105 and the oxide semiconductor film 109 is formed over the gate insulating film 107 so as to overlap with part of the gate electrode 105.

The gate insulating film 107 is formed by a sputtering method, a CVD method, an evaporation method, or the like.

Here, a silicon nitride film having a thickness of 50 nm is formed by a CVD method and then a silicon oxynitride film having a thickness of 200 nm is formed by a CVD method to form the gate insulating film 107.

A method for forming the oxide semiconductor film 109 is described below. First, an oxide semiconductor film is formed over the gate insulating film 107 by a sputtering method, a coating method, a pulsed laser deposition method, a laser ablation method, or the like. Next, a mask is formed over the oxide semiconductor film by a photolithography process and then part of the oxide semiconductor film is etched with use of the mask, whereby the oxide semiconductor film 109 that is subjected to element isolation can be formed.

Alternatively, by using a printing method for forming the oxide semiconductor film 109, the oxide semiconductor film 109 that is subjected to element isolation can be formed directly.

In the case where the oxide semiconductor film is formed by a sputtering method, a power supply device for generating plasma can be an RF power supply device, an AC power supply device, a DC power supply device, or the like as appropriate.

As a sputtering gas, a rare gas (typically argon) atmosphere, an oxygen atmosphere, or a mixed gas of a rare gas and oxygen is used as appropriate. In the case of using the mixed gas of a rare gas and oxygen, the proportion of oxygen is preferably higher than that of a rare gas.

Further, a target may be appropriately selected in accordance with the composition of the oxide semiconductor film to be formed.

Here, an oxide semiconductor film having a thickness of 35 nm is formed by a sputtering method and then a mask is formed over the oxide semiconductor film; part of the oxide semiconductor film is selectively etched to form the oxide semiconductor film 109.

Next, as illustrated in FIG. 2C, the pair of electrodes 111a and 111b is formed.

A method for forming the pair of electrodes 111a and 111b is described below. First, a conductive film is formed by a sputtering method, a CVD method, an evaporation method, or the like. Then, a mask is formed over the conductive film by a photolithography process. Next, the conductive film is etched with use of the mask to form the pair of electrodes 111a and 111b. After that, the mask is removed.

Here, a tungsten film having a thickness of 50 nm, an aluminum film having a thickness of 400 nm, and a titanium film having a thickness of 100 nm are stacked in this order by a sputtering method. Next, a mask is formed over the tungsten film by a photolithography process and the tungsten film, the aluminum film, and the titanium film are thy-etched with use of the mask to form the pair of electrodes 111a and 111b.

After the pair of electrodes 111a and 111b is formed, cleaning treatment is preferably performed to remove an etching residue. A short circuit of the pair of electrodes 111a and 111b can be suppressed by this cleaning treatment. The cleaning treatment can be performed using an alkaline solution such as a tetramethylammonium hydroxide (TMAH) solution, an acidic solution such as a diluted hydrofluoric acid solution or an oxalic acid solution, or water.

Next, as illustrated in FIG. 2D, the insulating film 113 is formed.

The insulating film 113 is formed by a sputtering method, a CVD method, a coating method, a printing method, or the like.

Here, as the insulating film 113, a silicon oxynitride film having a thickness of 400 nm is formed by a CVD method.

Through the above steps, the transistor 100 having excellent electric characteristics such as a sharp increase of the drain current at around the threshold voltage can be manufactured.

### Embodiment 2

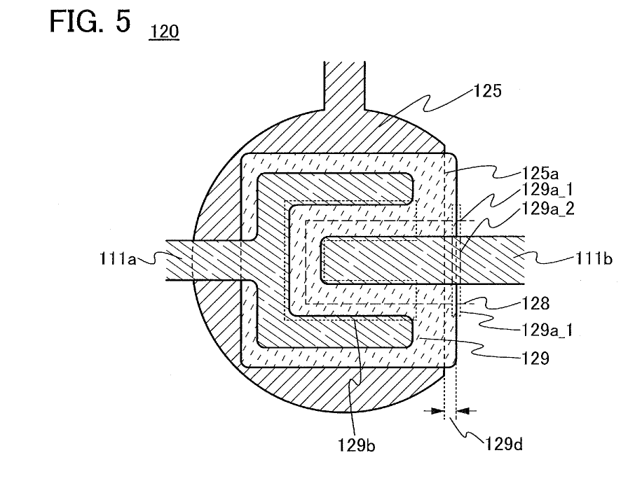

In this embodiment, a method for manufacturing a transistor having an upper surface shape different from that of the transistor described in Embodiment 1 is described with reference to FIG. 5.

FIG. 5 is a top view of a transistor 120 described in this embodiment. Note that the cross-sectional shape of the transistor 120 is similar to that of the transistor 100 illustrated in FIGS. 1A and 1B; therefore, the description thereof is omitted here.

The transistor 120 illustrated in FIG. 5 is different from the transistor 100 described in Embodiment 1 in that the shape of the oxide semiconductor film is different from that of the gate electrode overlapping with the oxide semiconductor film. For example, the oxide semiconductor film has one of a circular shape, a rectangular shape, or a polygonal shape and the gate electrode overlapping with the oxide semiconductor film has one of the above shapes other than the shape of the oxide semiconductor film.

FIG. 5 typically illustrates a top view of a transistor including the oxide semiconductor film 129 which has a rectangular upper surface and a gate electrode 125 which overlaps with the oxide semiconductor film 129 and has a shape formed by a curve and a straight line.

As illustrated in FIG. 5, as for the pair of electrodes 111a and 111b of the transistor 120 described in this embodiment, the electrode 111a partly surrounds an end portion and side surface portions of the electrode 111b. Specifically, the electrode 111a partly surrounds the electrode 111b with a certain space interposed therebetween. Note that in the oxide semiconductor film 109, a region where the pair of electrodes 111a and 111b face each other, that is, the region which is interposed between the electrode 111a and the electrode 111b and which overlaps with the gate electrode 125 serves as a channel region 129b.

Further, in the oxide semiconductor film 109, an end portion of the oxide semiconductor film which continuously extends from end portions of the channel region 129b does not overlap with the gate electrode 125. That is, as illustrated in FIG. 5, a region not overlapping with the gate electrode 125 is in the vicinity of the channel region 129b. Alternatively, the oxide semiconductor film 109 includes the region in contact with the channel region 129b and not overlapping with the gate electrode 125.

Further, a direction 128 extending from a channel width direction of the transistor 120, in other words, the direction 128 extending from a direction intersecting with a direction in which the electrodes 111a and 111b face each other (that is, channel length direction), and the end portion of the oxide semiconductor film 129 does not overlap with the gate electrode 125.

Furthermore, the oxide semiconductor film 129 includes a region 129d not overlapping with the gate electrode 125 between a region overlapping with the electrode 111a and an end portion 129a_2 overlapping with the electrode 111b. That is, in the oxide semiconductor film 129, the region 129d not overlapping with the gate electrode 125 is provided between the channel region 129b and the end portion of the oxide semiconductor film 129.

Further, in the oxide semiconductor film 129, linear end portions 129a_1 provided in the vicinity of the channel region 129b do not overlap with the gate electrode 125. That is, the end portions 129a_1 of the oxide semiconductor film 129 are positioned on the outer side than an end portion 125a of the gate electrode 125. Note that the end portions 129a_1 are adjacent to the end portion 129a_2 of the oxide semiconductor film overlapping with the electrode 111b and are the closest to the channel region 129b.

Thus, the end portions 129a_1 of the oxide semiconductor film in the vicinity of the channel region do not overlap with the gate electrode 125. That is, since the end portions 129a_1 of the oxide semiconductor film are positioned on the outer side than the gate electrode 125, an electric field is not applied to the end portions 129a_1 of the oxide semiconductor film and thus the end portions of the oxide semiconductor film do not become n-type; consequently, a leakage path is not caused. Thus, the transistor 120 can have excellent electric characteristics such as a sharp increase of the drain current at around the threshold voltage.

### Embodiment 3

In this embodiment, a method for manufacturing any of the transistors described in Embodiment 1 and Embodiment 2 in which the hydrogen concentration and oxygen vacancies in the oxide semiconductor film are reduced, is described with reference to FIGS. 2A to 2D. Note that at least one of steps described in this embodiment may be combined with the manufacturing steps of the transistor described in Embodiment 1; it is not necessary to combine all the steps in this embodiment with the manufacturing steps of the transistor described in Embodiment 1.

When the hydrogen concentration in the oxide semiconductor film 109 is less than 5×10¹⁹ atoms/cm³, preferably less than or equal to 5×10¹⁸ atoms/cm³, further preferably less than or equal to 5×10¹⁷ atoms/cm³, still further preferably 1×10¹⁶ atoms/cm³, the hydrogen concentration in the oxide semiconductor film 109 can be reduced.

Hydrogen contained in the oxide semiconductor film reacts with oxygen bonded to a metal atom to produce water, and a defect is formed in a lattice from which oxygen is released (or a portion from which oxygen is removed). Further, part of hydrogen serves as a donor to generate electrons that are carriers. Thus, the impurities containing hydrogen are reduced as much as possible in the formation step of the oxide semiconductor film, whereby the hydrogen concentration in the oxide semiconductor film can be reduced. Therefore, when a channel region is formed in an oxide semiconductor film that is highly purified by removing hydrogen as much as possible, the negative shift of the threshold voltage can be reduced and leakage current between a source and a drain of the transistor, typically, the off-state current density (a value obtained by dividing the off-state current by the channel width of the transistor) can be reduced to several yA/μm to several zA/μm; thus, electrical characteristics of the transistor can be improved.

As a first method for reducing the hydrogen concentration in the oxide semiconductor film, there is a method in which hydrogen or water contained in the substrate 101 is released by heat treatment or plasma treatment before the gate electrode 125 is formed. This method allows hydrogen or water attached to the substrate 101 to be prevented from diffusing into the oxide semiconductor film 109 in later heat treatment. The heat treatment is performed at a temperature higher than or equal to 100° C. and lower than the strain point of the substrate under an inert atmosphere, a reduced-pressure atmosphere, or a dry air atmosphere. Further, for the plasma treatment, rare gas, oxygen, nitrogen, or nitrogen oxide (e.g., nitrous oxide, nitrogen monoxide, or nitrogen dioxide) is used.

An electric furnace, an RTA apparatus, or the like can be used for the heat treatment. With use of the RTA apparatus, only in a short time, the heat treatment can be performed at a temperature higher than or equal to the strain point of the substrate. Thus, time during which hydrogen or water is released from the substrate can be shortened.

As a second method for reducing the hydrogen concentration in the oxide semiconductor film 109, there is a method in which before the oxide semiconductor film is formed by a sputtering apparatus, a dummy substrate is put into the sputtering apparatus, and an oxide semiconductor film is formed over the dummy substrate, so that hydrogen, water, or the like attached to the target surface or a deposition shield are removed. Thus, entry of hydrogen, water, or the like into the oxide semiconductor film can be reduced.

As a third method for reducing the hydrogen concentration in the oxide semiconductor film 109, for example, in the case where a sputtering method is employed in the formation of the oxide semiconductor film, there is a method in which the substrate temperature is set to higher than or equal to 150° C. and lower than or equal to 750° C., preferably higher than or equal to 150° C. and lower than or equal to 450° C., further preferably higher than or equal to 200° C. and lower than or equal to 350° C. and the oxide semiconductor film is formed. By this method, entry of hydrogen, water, or the like into the oxide semiconductor film can be reduced.

Here, a sputtering apparatus which can reduce the hydrogen concentration in the oxide semiconductor film is described in detail below.

The leakage rate of a treatment chamber in which the oxide semiconductor film is formed is preferably lower than or equal to 1×10⁻¹⁰ Pa·m³/sec., whereby entry of hydrogen, water, or the like into the film to be formed by a sputtering method can be decreased.

Evacuation of the treatment chamber in the sputtering apparatus is preferably performed with a rough vacuum pump such as a dry pump and a high vacuum pump such as a sputter ion pump, a turbo molecular pump, or a cryopump in appropriate combination. The turbo molecular pump has an outstanding capability in evacuating a large-sized molecule, whereas it has a low capability in evacuating hydrogen and water. Further, a combination with a sputter ion pump having a high capability in evacuating hydrogen or a cryopump having a high capability in evacuating water or is effective.

An adsorbate present at the inner wall of the treatment chamber does not affect the pressure in the treatment chamber because it is adsorbed on the inner wall, but the adsorbate leads to release of a gas at the time of the evacuation of the treatment chamber. Therefore, although the leakage rate and the evacuation rate do not have a correlation, it is important that the adsorbate present in the treatment chamber be desorbed as much as possible and evacuation be performed in advance with use of a pump having high evacuation capability. Note that the treatment chamber may be subjected to baking for promotion of desorption of the adsorbate. By the baking, the rate of desorption of the adsorbate can be increased about tenfold. The baking should be performed at a temperature higher than or equal to 100° C. and lower than or equal to 450° C. At this time, when the adsorbate is removed while an inert gas is introduced, the rate of desorption of water or the like, which is difficult to desorb only by evacuation, can be further increased.

As described above, in the process for forming the oxide semiconductor film, entry of impurities is suppressed as much as possible through control of the pressure of the treatment chamber, leakage rate of the treatment chamber, and the like, whereby entry of hydrogen, water, or the like into the oxide semiconductor film can be reduced.

As a fourth method for reducing the hydrogen concentration in the oxide semiconductor film 109, there is a method in which a high-purity gas from which impurities containing hydrogen are removed is used. This method allows reduction of entry of hydrogen, water, or the like into the oxide semiconductor film.

As a fifth method for reducing the hydrogen concentration in the oxide semiconductor film 109, there is a method in which the gate electrode 105 and the gate insulating film 107 are formed in this order over the substrate 101, the oxide semiconductor film is formed over the gate insulating film 107, and then heat treatment is performed. By the heat treatment, dehydrogenation or dehydration of the oxide semiconductor film can be performed.

The temperature of the heat treatment is typically higher than or equal to 150° C. and lower than the strain point of the substrate, preferably higher than or equal to 250° C. and lower than or equal to 450° C., further preferably higher than or equal to 300° C. and lower than or equal to 450° C.

An electric furnace, an RTA apparatus, or the like can be used for the heat treatment. With use of the RTA apparatus, only in a short time, the heat treatment can be performed at a temperature higher than or equal to the strain point of the substrate. Thus, time during which hydrogen or water is released from the oxide semiconductor film can be shortened.

The heat treatment is performed under an inert gas atmosphere containing nitrogen or a rare gas such as helium, neon, argon, xenon, or krypton. Alternatively, the heat treatment may be performed under an inert gas atmosphere first, and then under an oxygen atmosphere. It is preferable that the above inert gas atmosphere and the above oxygen atmosphere do not contain hydrogen, water, or the like. The treatment time is 3 minutes to 24 hours.

Note that the oxide semiconductor film is formed over the gate insulating film 107 and part of the oxide semiconductor film is etched to form the oxide semiconductor film 109 that is subjected to element isolation, and then the heat treatment for dehydration or dehydrogenation may be performed. Through the above process, hydrogen, water, or the like in the gate insulating film 107 can be efficiently released in the heat treatment for dehydration or dehydrogenation.

The heat treatment for dehydration or dehydrogenation may be performed plural times, and may also serve as another heat treatment.

As a sixth method for reducing the hydrogen concentration in the oxide semiconductor film 109, there is a method in which after the insulating film 113 is formed, heat treatment is performed. By the heat treatment, dehydrogenation or dehydration of the oxide semiconductor film can be performed. The heat treatment can be performed under the conditions similar to those in the fifth method. In addition, by using an insulating film that prevents entry of hydrogen, water, or the like from the outside such as an aluminum oxide film or an aluminum oxynitride film as the insulating film 113, entry of hydrogen, water, or the like from the outside into the oxide semiconductor film can be reduced.

By combination of at least one of the first to sixth methods for reducing the hydrogen concentration in the oxide semiconductor film 109 and the manufacturing method of the transistor described in Embodiment 1, a transistor whose channel region is formed in an oxide semiconductor film that is highly purified by removing hydrogen, water, or the like as much as possible can be manufactured. Thus, the negative shift of the threshold voltage can be reduced and leakage current between a source and a drain of the transistor, typically, the off-state current density (a value obtained by dividing the off-state current by the channel width of the transistor) can be reduced to several yA/μm to several zA/μm; thus, electrical characteristics of the transistor can be improved. Further, the end portions of the oxide semiconductor film provided in the vicinity of the channel region do not overlap with the gate electrode; therefore, an electric field is not applied to the end portions of the oxide semiconductor film and thus the end portions of the oxide semiconductor film do not become n-type; consequently, a leakage path is not caused. From the above, according to this embodiment, a transistor in which the negative shift of the threshold voltage is reduced and the leakage current is reduced and which has excellent electrical characteristics such as a sharp increase of the drain current at around the threshold voltage can be manufactured.

### Embodiment 4

In this embodiment, a method for manufacturing any of the transistors described in Embodiment 1 to Embodiment 3 in which oxygen vacancies in the oxide semiconductor film are reduced is described with reference to FIGS. 2A to 2D. Note that at least one of steps described in this embodiment may be combined with the manufacturing steps of any of the transistors described in Embodiment 1 to Embodiment 3; it is not necessary to combine all the steps in this embodiment with the manufacturing steps of any of the transistors described in Embodiment 1 to Embodiment 3.

Oxygen contained in the oxide semiconductor film is released by heat treatment. Therefore, by addition of oxygen to the oxide semiconductor film, a change in the electrical characteristics of the transistor, which is caused by oxygen vacancies, can be reduced, whereby reliability can be improved. The oxide semiconductor film to which oxygen is added preferably contains oxygen in the proportion exceeding the stoichiometric proportion.

As a first method for reducing oxygen vacancies in the oxide semiconductor film, there is a method in which after the gate insulating film 107 illustrated in FIG. 2B is formed, oxygen is added to the gate insulating film 107; and then after the oxide semiconductor film 109 is formed over the gate insulating film 107, heat treatment is performed, so that oxygen contained in the gate insulating film 107 is diffused into the oxide semiconductor film 109.

Oxygen can be added to the gate insulating film 107 by an ion implantation method, an ion doping method, plasma treatment, or the like.

The heat treatment performed after the formation of the oxide semiconductor film 109 may be performed as appropriate under the conditions similar to those in the fifth method for reducing the hydrogen concentration in the oxide semiconductor film 109, which is described in Embodiment 3. Alternatively, the fifth method for reducing the hydrogen concentration in the oxide semiconductor film 109 may also serve as the heat treatment for reducing oxygen vacancies in the oxide semiconductor film.

As a second method for reducing oxygen vacancies in the oxide semiconductor film, there is a method in which after the oxide semiconductor film 109 illustrated in FIG. 2B is formed, oxygen is added to the oxide semiconductor film 109. Oxygen can be added to the oxide semiconductor film 109 by the method in which oxygen is added to the gate insulating film 107 described in the first method for reducing oxygen vacancies in the oxide semiconductor film as appropriate.

As a third method for reducing oxygen vacancies in the oxide semiconductor film, there is a method in which after the insulating film 113 illustrated in FIG. 2D is formed, oxygen is added to the oxide semiconductor film 109 through the insulating film 113. Oxygen can be added to the oxide semiconductor film 109 by the method in which oxygen is added to the gate insulating film 107 described in the first method for reducing oxygen vacancies in the oxide semiconductor film as appropriate.

As a fourth method for reducing oxygen vacancies in the oxide semiconductor film, there is a method in which after the insulating film 113 illustrated in FIG. 2D is formed, oxygen is added to the insulating film 113, and then heat treatment is performed, so that oxygen contained in the insulating film 113 is diffused into the oxide semiconductor film 109. Oxygen can be added to the insulating film 113 by the method in which oxygen is added to the gate insulating film 107 described in the first method for reducing oxygen vacancies in the oxide semiconductor film as appropriate. The heat treatment performed after addition of oxygen may be performed under the conditions similar to those in the sixth method for reducing the hydrogen concentration in the oxide semiconductor film 109, which is described in Embodiment 3. Alternatively, the sixth method for reducing the hydrogen concentration in the oxide semiconductor film 109 may also serve as the heat treatment for diffusing oxygen contained in the insulating film 113 into the oxide semiconductor film 109.

Note that by using an insulating film that prevents diffusion of oxygen to the outside such as an aluminum oxide film or an aluminum oxynitride film as the insulating film 113, oxygen released from the gate insulating film 107 can be efficiently supplied to the oxide semiconductor film 109. In addition, release of oxygen from the oxide semiconductor film 109 can be suppressed.

Further, when the insulating film 113 has a stacked-layer structure where an insulating film from which part of oxygen is released by heating is provided on the side in contact with the oxide semiconductor film 109 and an insulating film which prevents diffusion of oxygen is provided over the insulating film, oxygen contained in the insulating film from which part of oxygen is released by heating can be efficiently supplied to the oxide semiconductor film 109. The insulating film from which part of oxygen is released by heating is preferably an insulating film which contains oxygen at a proportion exceeding the stoichiometric proportion.

In the first method and the fourth method, oxygen is added to the oxide semiconductor film 109 not by direct addition but by solid-phase diffusion from the gate insulating film 107 or the insulating film 113 to which oxygen is added; thus, the oxide semiconductor film 109 can be less damaged.

By combination of at least one of the first to fourth method for reducing oxygen vacancies in the oxide semiconductor film 109 and the manufacturing method of the transistor described in Embodiment 1, a transistor whose channel region is formed in an oxide semiconductor film in which oxygen vacancies are reduced can be manufactured. Further, in the transistor described in this embodiment, the end portions of the oxide semiconductor film in the vicinity of the channel region do not overlap with the gate electrode; therefore, an electric field is not applied to the end portions of the oxide semiconductor film and thus the end portions of the oxide semiconductor film do not become n-type; consequently, a leakage path is not caused. From the above, according to this embodiment, a transistor in which a change in the electrical characteristics is reduced and which has excellent electrical characteristics such as a sharp increase of the drain current at around the threshold voltage can be manufactured.

Further, by combination of at least one of the first to fourth methods for reducing oxygen vacancies in the oxide semiconductor film 109 and at least one of the first to sixth methods for reducing the hydrogen concentration, which are described in Embodiment 3, with the manufacturing method of the transistor described in Embodiment 1, a transistor whose channel region is formed in an oxide semiconductor film which is highly purified by removing hydrogen, water, or the like as much as possible and in which oxygen deficiencies are reduced can be manufactured. Further, in the transistor described in this embodiment, the end portions of the oxide semiconductor film provided in the vicinity of the channel region do not overlap with the gate electrode; therefore, an electric field is not applied to the end portions of the oxide semiconductor film and thus the end portions of the oxide semiconductor film do not become n-type; consequently, a leakage path is not caused. From the above, a transistor in which the negative shift of the threshold voltage is reduced, the leakage current is reduced, and a change in the electrical characteristics of the transistor is reduced, and which has excellent electrical characteristics such as a sharp increase of the drain current at around the threshold voltage can be manufactured.

### Embodiment 5

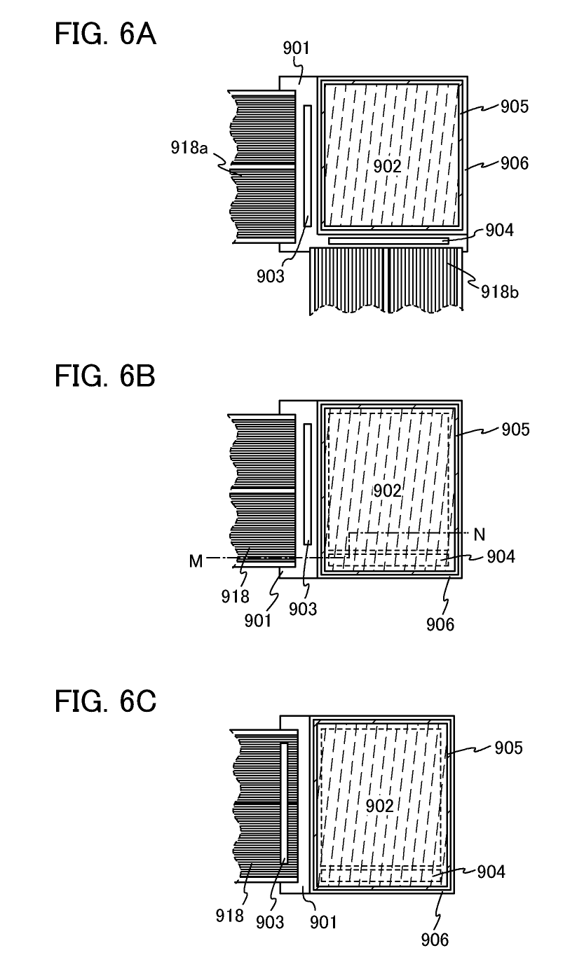

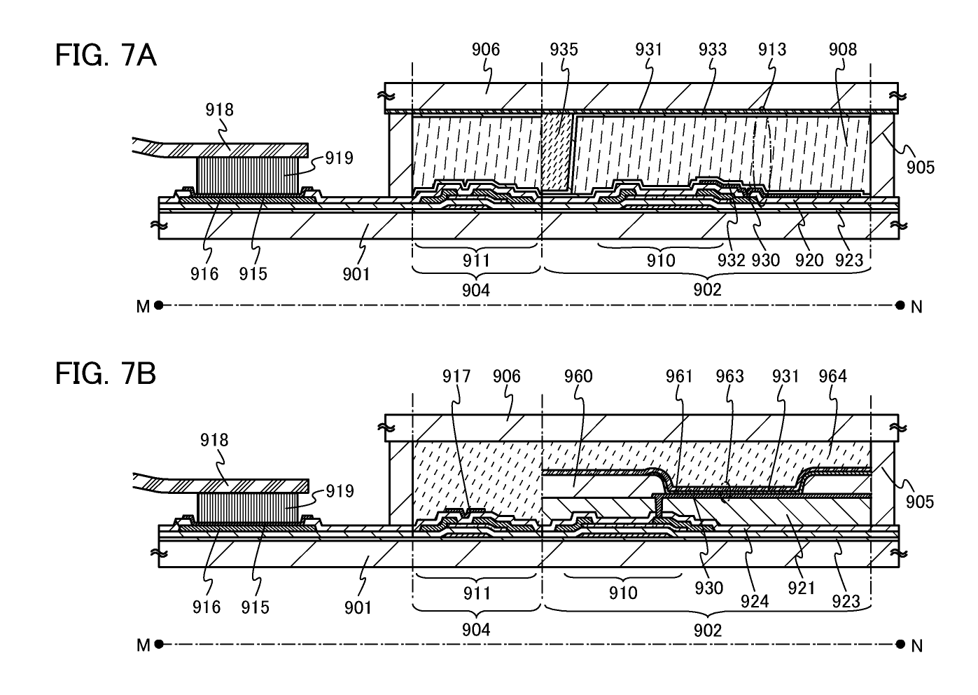

A semiconductor device (also referred to as a display device) having a display function can be manufactured using the transistor an example of which is described in the above embodiments. Moreover, some or all of the driver circuits which include the transistor can be formed over a substrate where the pixel portion is formed, whereby a system-on-panel can be obtained. In this embodiment, an example of a display device including the transistor whose example is described in any of the above embodiments is described with reference to FIGS. 6A to 6C and FIGS. 7A and 7B. FIGS. 7A and 7B are cross-sectional views illustrating cross-sectional structures taken along a dashed-dotted line M-N in FIG. 6B.

In FIG. 6A, a sealant 905 is provided so as to surround a pixel portion 902 provided over a first substrate 901, and the pixel portion 902 is sealed by the sealant 905 and a second substrate 906. In FIG. 6A, a scan line driver circuit 904 and a signal line driver circuit 903 each are formed using a single-crystal semiconductor or a polycrystalline semiconductor over a substrate prepared separately, and mounted in a region different from the region surrounded by the sealant 905 over the first substrate 901. Various signals and potentials are supplied to the signal line driver circuit 903, the scan line driver circuit 904, and the pixel portion 902 each of which is separately formed from flexible printed circuits (FPCs) 918a and 918b.

In FIGS. 6B and 6C, the sealant 905 is provided so as to surround the pixel portion 902 and the scan line driver circuit 904 which are provided over the first substrate 901. The second substrate 906 is provided over the pixel portion 902 and the scan line driver circuit 904. Thus, the pixel portion 902 and the scan line driver circuit 904 are sealed together with a display element by the first substrate 901, the sealant 905, and the second substrate 906. In FIGS. 6B and 6C, a signal line driver circuit 903 which is formed using a single crystal semiconductor or a polycrystalline semiconductor over a substrate separately prepared is mounted in a region different from the region surrounded by the sealant 905 over the first substrate 901. In FIGS. 6B and 6C, a variety of signals and potentials are supplied to the signal line driver circuit 903 which is separately formed, the scan line driver circuit 904, and the pixel portion 902 from an FPC 918.

Although FIGS. 6B and 6C each illustrate an example in which the signal line driver circuit 903 is formed separately and mounted on the first substrate 901, the present invention is not limited to this structure. The scan line driver circuit may be separately formed and then mounted, or only part of the signal line driver circuit or part of the scan line driver circuit may be separately formed and then mounted.

Note that a connection method of a separately formed driver circuit is not particularly limited, and a chip on glass (COG) method, a wire bonding method, a tape automated bonding (TAB) method or the like can be used. FIG. 6A shows an example in which the signal line driver circuit 903 and the scan line driver circuit 904 are mounted by a COG method. FIG. 6B shows an example in which the signal line driver circuit 903 is mounted by a COG method. FIG. 6C shows an example in which the signal line driver circuit 903 is mounted by a TAB method.

The display device includes, in its category, a panel in which a display element is sealed, and a module in which an IC or the like including a controller is mounted on the panel.

A display device in this specification refers to an image display device, a display device, or a light source (including a lighting device). Furthermore, the display device also includes the following modules in its category: a module to which a connector such as an FPC, or a TCP is attached; a module having a TCP at the tip of which a printed wiring board is provided; and a module in which an integrated circuit (IC) is directly mounted on a display element by a COG method.

The pixel portion and the scan line driver circuit provided over the first substrate include a plurality of transistors and any of the transistors which are described in the above embodiments can be applied.

As a display element provided in the display device, a liquid crystal element (also referred to as a liquid crystal display element) or a light-emitting element (also referred to as a light-emitting display element) can be used. A light emitting element includes, in its scope, an element whose luminance is controlled by current or voltage, and specifically includes an inorganic electroluminescent (EL) element, an organic EL element, and the like. Furthermore, a display medium whose contrast is changed by an electric effect, such as electronic ink, can be used.

As illustrated in FIGS. 7A and 7B, the semiconductor device includes a connection terminal electrode 915 and a terminal electrode 916. The connection terminal electrode 915 and the terminal electrode 916 are electrically connected to a terminal included in the FPC 918 through an anisotropic conductive agent 919.

The connection terminal electrode 915 is formed using the same conductive film as a first electrode 930, and the terminal electrode 916 is formed using the same conductive film as a pair of electrodes of transistors 910 and 911.

Each of the pixel portion 902 and the scan line driver circuit 904 which are provided over the first substrate 901 includes a plurality of transistors. FIGS. 7A and 7B illustrate the transistor 910 included in the pixel portion 902 and the transistor 911 included in the scan line driver circuit 904. In FIG. 7A, an insulating film 920 is formed over the transistors 910 and 911. In FIG. 7B, a planarization film 921 is further provided over an insulating film 924. Note that an insulating film 923 is an insulating film serving as a base film.

In this embodiment, any of the transistors described in the above embodiments can be applied to the transistors 910 and 911.

FIG. 7B illustrates an example in which a conductive film 917 is provided over the insulating film 924 so as to overlap with a channel formation region of the oxide semiconductor film of the transistor 911 for the driver circuit. In this embodiment, the conductive film 917 is formed of the same film as the first electrode 930. By providing the conductive film 917 so as to overlap with the channel formation region of the oxide semiconductor film, the amount of change in the threshold voltage of the transistor 911 by a BT test can be further reduced. The potential applied to the conductive film 917 is either the same as or different from the potential applied to the gate electrode of the transistor 911, and the conductive film can function as a second gate electrode. The potential of the conductive film 917 may be GND, 0 V, or in a floating state.

In addition, the conductive film 917 has a function of blocking an external electric field. In other words, the conductive film 917 has a function of preventing an external electric field (particularly, a function of preventing static electricity) from affecting the inside (a circuit portion including a thin film transistor). Such a blocking function of the conductive film 917 can prevent variation in electric characteristics of the transistor due to the influence of an external electric field such as static electricity. The conductive film 917 can be used for any of the transistors described in the above embodiments.

The transistor 910 provided in the pixel portion 902 is electrically connected to the display element to form a display panel. There is no particular limitation on the kind of the display element as long as display can be performed, and various kinds of display elements can be employed.

An example of a liquid crystal display device using a liquid crystal element as a display element is shown in FIG. 7A. In FIG. 7A, a liquid crystal element 913 is a display element including the first electrode 930, a second electrode 931, and a liquid crystal layer 908. An insulating film 932 and an insulating film 933 which serve as alignment films are provided so that the liquid crystal layer 908 is interposed therebetween. The second electrode 931 is formed on the second substrate 906 side. The second electrode 931 overlaps with the first electrode 930 with the liquid crystal layer 908 interposed therebetween.

A spacer 935 is a columnar spacer obtained by selective etching of an insulating film and is provided in order to control the distance between the first electrode 930 and the second electrode 931 (a cell gap). Alternatively, a spherical spacer may also be used.

In the case where a liquid crystal element is used as the display element, a thermotropic liquid crystal, a low-molecular liquid crystal, a high-molecular liquid crystal, a polymer dispersed liquid crystal, a ferroelectric liquid crystal, an anti-ferroelectric liquid crystal, or the like can be used. These liquid crystal materials exhibit a cholesteric phase, a smectic phase, a cubic phase, a chiral nematic phase, an isotropic phase, or the like depending on conditions.

Alternatively, liquid crystal exhibiting a blue phase for which an alignment film is unnecessary may be used. A blue phase is one of liquid crystal phases, which is generated just before a cholesteric phase changes into an isotropic phase while temperature of cholesteric liquid crystal is increased. Since the blue phase appears only in a narrow temperature range, a liquid crystal composition in which a chiral material is mixed is used for the liquid crystal layer in order to improve the temperature range. The liquid crystal composition which includes a liquid crystal exhibiting a blue phase and a chiral agent has a short response time of 1 msec. or less, and has optical isotropy, which makes the alignment process unneeded and viewing angle dependence small. In addition, since an alignment film does not need to be provided and rubbing treatment is unnecessary, electrostatic discharge damage caused by the rubbing treatment can be prevented and defects and damage of the liquid crystal display device can be reduced in the manufacturing process. Thus, productivity of the liquid crystal display device can be increased.

Further, the transistor including an oxide semiconductor film used in the above embodiments has the following electrical characteristics: a defect of a stepwise rise of the drain current does not occur. Therefore, switching characteristics are excellent. Furthermore, relatively high field-effect mobility is obtained, which enables high-speed operation. Consequently, when the above transistor is used in a pixel portion of a semiconductor device having a display function, high-quality images can be obtained. Since a driver circuit portion and the pixel portion can be formed over one substrate with the use of the above transistor, the number of components of the semiconductor device can be reduced.

The size of storage capacitor formed in the liquid crystal display device is set considering the leakage current of the transistor provided in the pixel portion or the like so that charge can be held for a predetermined period. By using the transistor including the highly-purified oxide semiconductor film, it is enough to provide a storage capacitor having a capacitance that is ⅓ or less, preferably ⅕ or less of a liquid crystal capacitance of each pixel; therefore, the aperture ratio of a pixel can be increased.

In the display device, a black matrix (light-blocking film), an optical member (optical substrate) such as a polarizing member, a retardation member, or an anti-reflection member, and the like are provided as appropriate. For example, circular polarization may be obtained by using a polarizing substrate and a retardation substrate. In addition, a backlight, a side light, or the like may be used as a light source.

As a display method in the pixel portion, a progressive method, an interlace method or the like can be employed. Further, color elements controlled in a pixel at the time of color display are not limited to three colors: R, G, and B (R, G, and B correspond to red, green, and blue, respectively). For example, R, G, B, and W (W corresponds to white); R, G, B, and one or more of yellow, cyan, magenta, and the like; or the like can be used. Further, the sizes of display regions may be different between respective dots of color elements. The present invention is not limited to the application to a display device for color display but can also be applied to a display device for monochrome display.

Alternatively, as the display element included in the display device, a light-emitting element utilizing electroluminescence can be used. Light-emitting elements utilizing electroluminescence are classified according to whether a light-emitting material is an organic compound or an inorganic compound. In general, the former is referred to as an organic EL element, and the latter is referred to as an inorganic EL element.

In an organic EL element, by application of voltage to a light-emitting element, electrons and holes are separately injected from a pair of electrodes into a layer containing a light-emitting organic compound, and current flows. The carriers (electrons and holes) are recombined, and thus, the light-emitting organic compound is excited. The light-emitting organic compound returns to a ground state from the excited state, thereby emitting light. Owing to such a mechanism, this light-emitting element is referred to as a current-excitation light-emitting element.

The inorganic EL elements are classified according to their element structures into a dispersion-type inorganic EL element and a thin-film inorganic EL element. A dispersion-type inorganic EL element has a light-emitting layer where particles of a light-emitting material are dispersed in a binder, and its light emission mechanism is donor-acceptor recombination type light emission that utilizes a donor level and an acceptor level. A thin-film inorganic EL element has a structure where a light-emitting layer is sandwiched between dielectric layers, which are further sandwiched between electrodes, and its light emission mechanism is localized type light emission that utilizes inner-shell electron transition of metal ions. Note that an example of an organic EL element as a light-emitting element is described here.

In order to extract light emitted from the light-emitting element, it is acceptable as long as at least one of a pair of electrodes is transparent. A transistor and a light-emitting element are formed over a substrate. The light-emitting element can have a top emission structure in which light emission is extracted through the surface opposite to the substrate; a bottom emission structure in which light emission is extracted through the surface on the substrate side; or a dual emission structure in which light emission is extracted through the surface opposite to the substrate and the surface on the substrate side, and a light-emitting element having any of these emission structures can be used.

FIG. 7B illustrates an example of a light-emitting device in which a light-emitting element is used as a display element. A light-emitting element 963 which is a display element is electrically connected to the transistor 910 provided in the pixel portion 902. Note that the structure of the light-emitting element 963 is a stacked structure of the first electrode 930, a light-emitting layer 961, and the second electrode 931; however, the structure is not limited thereto. The structure of the light-emitting element 963 can be changed as appropriate depending on, for example, the direction in which light is extracted from the light-emitting element 963.

A partition wall 960 can be formed using an organic insulating material or an inorganic insulating material. It is particularly preferable that the partition wall 960 be formed using a photosensitive resin material to have an opening over each of the first electrode 930 so that a sidewall of the opening has an inclined surface with a continuous curvature.

The light-emitting layer 961 may be formed with a single layer or a plurality of layers stacked.

A protective layer may be formed over the second electrode 931 and the partition wall 960 in order to prevent entry of oxygen, hydrogen, moisture, carbon dioxide, or the like into the light-emitting element 963. As the protective layer, a silicon nitride film, a silicon nitride oxide film, an aluminum oxide film, an aluminum nitride film, an aluminum oxynitride film, an aluminum nitride oxide film, a DLC film, or the like can be formed. In addition, in a space which is sealed with the first substrate 901, the second substrate 906, and the sealant 905, a filler 964 is provided and sealed. It is preferable that a panel be packaged (sealed) with a protective film (such as a laminate film or an ultraviolet curable resin film) or a cover material with high air-tightness and little degasification so that the panel is not exposed to the outside air, in this manner.

As the filler 964, as well as an inert gas such as nitrogen or argon, an ultraviolet curable resin or a thermosetting resin can be used; polyvinyl chloride (PVC), an acrylic resin, polyimide, an epoxy resin, a silicone resin, polyvinyl butyral (PVB), ethylene vinyl acetate (EVA), or the like can be used. For example, nitrogen is used for the filler.

In addition, if needed, an optical film, such as a polarizing plate, a circularly polarizing plate (including an elliptically polarizing plate), a retardation plate (a quarter-wave plate or a half-wave plate), or a color filter, may be provided as appropriate on a light-emitting surface of the light-emitting element. Further, the polarizing plate or the circularly polarizing plate may be provided with an anti-reflection film. For example, anti-glare treatment by which reflected light can be diffused by projections and depressions on the surface so as to reduce the glare can be performed.

The first electrode and the second electrode (each of which may be called a pixel electrode, a common electrode, a counter electrode, or the like) for applying voltage to the display element may have light-transmitting properties or light-reflecting properties, which depends on the direction in which light is extracted, the position where the electrode is provided, and the pattern structure of the electrode.

The first electrode 930 and the second electrode 931 can be formed using a light-transmitting conductive material such as indium oxide including tungsten oxide, indium zinc oxide including tungsten oxide, indium oxide including titanium oxide, indium tin oxide including titanium oxide, indium tin oxide (hereinafter referred to as ITO), indium zinc oxide, or indium tin oxide to which silicon oxide is added.

Alternatively, the first electrode 930 and the second electrode 931 can be formed using one or more materials selected from metals such as tungsten (W), molybdenum (Mo), zirconium (Zr), hafnium (Hf), vanadium (V), niobium (Nb), tantalum (Ta), chromium (Cr), cobalt (Co), nickel (Ni), titanium (Ti), platinum (Pt), aluminum (Al), copper (Cu), and silver (Ag); an alloy of any of these metals; and a nitride of any of these metals.

The first electrode 930 and the second electrode 931 can be formed using a conductive composition including a conductive macromolecule (also referred to as a conductive polymer). As the conductive high molecule, what is called a π-electron conjugated conductive polymer can be used. For example, polyaniline or a derivative thereof, polypyrrole or a derivative thereof, polythiophene or a derivative thereof, a copolymer of two or more of aniline, pyrrole, and thiophene or a derivative thereof, and the like can be given.

Since the transistor is easily broken owing to static electricity or the like, a protective circuit for protecting the driver circuit is preferably provided. The protection circuit is preferably formed using a nonlinear element.

As described above, by using any of the transistors described in the above embodiments, a semiconductor device having a display function and high reliability can be provided.

This embodiment can be implemented in appropriate combination with any structure described in the other embodiments.

This application is based on Japanese Patent Application serial no. 2012-057738 filed with Japan Patent Office on Mar. 14, 2012, the entire contents of which are hereby incorporated by reference.

What is claimed is:

1. A semiconductor device comprising:
a gate electrode;
a gate insulating film adjacent to the gate electrode;
an oxide semiconductor film overlapping with the gate electrode with the gate insulating film located therebetween;
a first electrode electrically connected to the oxide semiconductor film, the first electrode intersecting with a first edge of the oxide semiconductor film and a second edge of the gate electrode; and
a second electrode electrically connected to the oxide semiconductor film,
wherein the first electrode is interposed between a first part of the second electrode and a second part of the second electrode,
wherein the gate electrode does not overlap with the first edge,
wherein the second electrode does not overlap with the second edge, and
wherein the first electrode is in contact with a side surface of the oxide semiconductor film.

2. The semiconductor device according to claim 1, wherein the oxide semiconductor film comprises one or more elements selected from the group consisting of indium, gallium, tin, and zinc.

3. The semiconductor device according to claim 1, wherein the oxide semiconductor film comprises indium, gallium, and zinc.

4. The semiconductor device according to claim 1, wherein the gate electrode is located under the oxide semiconductor film.

5. The semiconductor device according to claim 1, wherein an end portion of the oxide semiconductor film continuing from an end portion of a channel region of the oxide semiconductor film does not overlap with the gate electrode.

6. The semiconductor device according to claim 1,
wherein the oxide semiconductor film comprises a crystal part in which a c-axis is aligned in a direction substantially parallel to a normal vector of a surface of the oxide semiconductor film.

7. The semiconductor device according to claim 1, further comprising an insulating film over and in contact with a top surface of the oxide semiconductor film, a top surface of the first electrode, and a top surface of the second electrode.

8. A semiconductor device comprising:
a gate electrode;
a gate insulating film adjacent to the gate electrode;
an oxide semiconductor film overlapping with the gate electrode with the gate insulating film located therebetween;
a first electrode electrically connected to the oxide semiconductor film; and
a second electrode electrically connected to the oxide semiconductor film,
wherein the first electrode is interposed between a first part of the second electrode and a second part of the second electrode,
wherein each of a first edge of the oxide semiconductor film and a second edge of the gate electrode intersects with a direction extending a channel width direction of the oxide semiconductor film,
wherein the gate electrode does not overlap with the first edge,
wherein the second electrode does not overlap with the second edge, and
wherein the first electrode is in contact with a side surface of the oxide semiconductor film.

9. The semiconductor device according to claim 8, wherein the oxide semiconductor film comprises one or more elements selected from the group consisting of indium, gallium, tin, and zinc.

10. The semiconductor device according to claim 8, wherein the oxide semiconductor film comprises indium, gallium, and zinc.

11. The semiconductor device according to claim 8, wherein the gate electrode is located under the oxide semiconductor film.

12. The semiconductor device according to claim 8,
wherein the oxide semiconductor film comprises a crystal part in which a c-axis is aligned in a direction substantially parallel to a normal vector of a surface of the oxide semiconductor film.

13. The semiconductor device according to claim 8, further comprising an insulating film over and in contact with a top surface of the oxide semiconductor film, a top surface of the first electrode, and a top surface of the second electrode.

14. A semiconductor device comprising:
a gate electrode;
a gate insulating film adjacent to the gate electrode;
an oxide semiconductor film overlapping with the gate electrode with the gate insulating film located therebetween;
a first electrode electrically connected to the oxide semiconductor film, the first electrode intersecting with a first edge of the oxide semiconductor film and a second edge of the gate electrode;
a second electrode electrically connected to the oxide semiconductor film,
wherein the first electrode is interposed between a first part of the second electrode and a second part of the second electrode, and
wherein the oxide semiconductor film comprises a channel region located between the first electrode and the second electrode and overlapping with the gate electrode,
wherein the oxide semiconductor film comprises a region located between the first edge and the channel region and not overlapping with the gate electrode,
wherein the second electrode does not overlap with the second edge, and
wherein the first electrode is in contact with a side surface of the oxide semiconductor film.

15. The semiconductor device according to claim 14, wherein the oxide semiconductor film comprises one or more elements selected from the group consisting of indium, gallium, tin, and zinc.

16. The semiconductor device according to claim 14, wherein the oxide semiconductor film comprises indium, gallium, and zinc.

17. The semiconductor device according to claim 14, wherein the gate electrode is located under the oxide semiconductor film.

18. The semiconductor device according to claim 14,
wherein the oxide semiconductor film comprises a crystal part in which a c-axis is aligned in a direction substantially parallel to a normal vector of a surface of the oxide semiconductor film.

19. The semiconductor device according to claim 14, further comprising an insulating film over and in contact with a top surface of the oxide semiconductor film, a top surface of the first electrode, and a top surface of the second electrode.
